(19) United States
(12) Patent Application Publication
(10) Pub. No.: US 2025/0387863 A1
(43) Pub. Date: Dec. 25, 2025

(54) ELECTROCHEMICAL POLISHING METHOD EMPLOYING SOLID ELECTRO-CONDUCTIVE MEDIA WITH BI-DIRECTIONAL PLANETARY MOTION

(71) Applicant: Beijing Institute of Technology, Beijing (CN)

(72) Inventors: Chaojiang Li, Beijing (CN); Shenggui Liu, Beijing (CN); Xin Jin, Beijing (CN); Guodong Liu, Beijing (CN); Zilong Guo, Beijing (CN); Yuxin Yang, Beijing (CN)

(21) Appl. No.: 18/812,972

(22) Filed: Aug. 22, 2024

(30) Foreign Application Priority Data
Jun. 20, 2024 (CN) 202410797690.1

(51) Int. Cl. B24B 1/00; B24B 31/00

(52) U.S. Cl. CPC B24B 1/002; B24B 31/003

(57) ABSTRACT

Disclosed is an electrochemical polishing method employing solid electro-conductive media with bi-directional planetary motion, mainly including the following steps: using solid particles absorbing an electrolyte as solid electro-conductive media, and submerging an anode (workpiece) in the solid electro-conductive media to perform bi-directional planetary motion during polishing, allowing the workpiece to fully contact and collide with the solid electro-conductive media, and ensuring that materials are uniformly removed from various surfaces of the workpiece. In the present disclosure, one-time overall polishing of complex-shaped workpieces can be achieved by bi-directional planetary motion of the workpieces, the consistency of material removal from various surfaces of the workpieces is improved, and the polishing performance and efficiency are enhanced.

### CROSS-REFERENCE TO RELATED APPLICATIONS

This application claims priority of Chinese Patent Application No. 202410797690.1, filed on Jun. 20, 2024, the entire contents of which are incorporated herein by reference.

### TECHNICAL FIELD

The present disclosure relates to the field of electrochemical polishing, and specifically relates to an electrochemical polishing method employing solid electro-conductive media with bi-directional planetary motion.

### BACKGROUND

With the rapid advancement of modern science and technology, numerous sectors such as aerospace, machinery and electronics demand cutting-edge products that exhibit high precision and reliability. These products must function stably and reliably under high temperature, high pressure, heavy loads, or corrosive environment over extended periods. Consequently, there are increasingly stringent requirements for the parts' mechanical properties and surface quality. The surface quality of metal parts significantly influences the service life, corrosion resistance, fatigue resistance, and wear resistance of mechanical products, directly impacting mechanical breakdowns and failures. As a final procedure of parts processing, polishing enhances the surface quality of the parts, allowing them to meet specific functional requirements. Therefore, polishing metal parts is crucial in many aspects of modern manufacturing, especially in ultra-precision manufacturing.

Electrochemical polishing, also known as anodic polishing or electrolytic polishing, is a precision finishing technique based on the principle of anodic dissolution for removing material from metals or alloys. This method removes material from the workpiece surface on an ion-by-ion basis, offering ultra-high precision and flexible controllability while remaining a non-contact and non-destructive machining process. Electrochemical polishing is widely applied in the metal precision finishing industry due to the simplicity of its apparatus and adaptability to addressing complex structures.

In addition, during electrochemical polishing, the metal atoms of the anode (workpiece) are oxidized to metal ions, which then accumulate near the anode. Due to the limited diffusion speed of these cations, they form a sticky layer on the anode surface, thereby slowing down the electrochemical reaction. As a result, the ion transfer process on the anode surface typically becomes the rate-limiting step of the electrochemical reaction. In conventional electrochemical polishing, solutions such as aqueous or deep eutectic solvents serve as electro-conductive media. The continuity of the fluid often necessitates stirring to enhance the ion transfer on the anode surface. Ion transfer in liquid media primarily occurs through convection, diffusion, and electromigration, with convection being the most effective means of enhancing the ion transfer rate.

However, in the traditional electrochemical polishing industry, a significant amount of water is required to prepare electrolytes, leading to the production of substantial volumes of contaminated and challenging-to-treat wastewater. The wastewater typically contains not only strong corrosive acids but also a large number of heavy metal ions, making it difficult to treat and resulting in severe environmental pollution if discharged improperly.

### SUMMARY

In response to the technical problem in prior art where electrochemical polishing employing liquid conductive media produces substantial volumes of contaminated and challenging-to-treat wastewater, the present disclosure provides an electrochemical polishing method employing solid electro-conductive media with bi-directional planetary motion.

To solve the above technical problem, the present disclosure provides the following technical solutions.

An electrochemical polishing method employing solid electro-conductive media with bi-directional planetary motion includes:
submerging a workpiece in solid electro-conductive media inside a cathode container, connecting the workpiece and the cathode container to a positive pole and a negative pole of a polishing power source, to serve as an anode and a cathode, respectively; and
driving the workpiece to perform planetary motion in the solid electro-conductive media along an inner wall of the cathode container while turning on the polishing power supply to polish the workpiece.

The planetary motion includes: revolution motion with an angular velocity of ω₁ and rotation motion with an angular velocity of ω₂, both always in the same direction, and reversed at least once in one planetary motion period T.

Preferably, in the one planetary motion period T, the time when ω₁ and ω₂ are forward and reverse is T/2.

Preferably, the solid electro-conductive media are spherical particles, having a diameter in the range of 0.1-2.0 mm and pore structures internally, and are formed by styrene or acrylic acid ion exchange resin.

Preferably, the pore structures in the electro-conductive media serve to store electrolytes, making solid dielectrics electrically conductive in the polishing process.

Preferably, the cathode container is electrically conductive and made of stainless steel.

Preferably, the power supply is a pulsed direct current power supply with a pulse period of 0.1-1 ms and a duty ratio of 50%-90%.

Preferably, the workpiece is connected to the positive pole of the polishing power supply via an electro-conductive slip ring during the planetary motion.

Preferably, the planetary motion period T is 1-40 min.

The present disclosure provides an electrochemical polishing device employing solid electro-conductive media with bi-directional planetary motion, which is used for performing the electrochemical polishing method employing solid electro-conductive media with bi-directional planetary motion, and includes:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

Preferably, the workpiece is connected to the positive pole of the polishing power supply via an electro-conductive slip ring assembly; the drive member including:
a revolution platform and a rotation connecting rod mounted thereon, the workpiece being mounted at a tail end of the rotation connecting rod, and the revolution platform and the rotation connecting rod being connected to a revolution drive motor and a rotation drive motor, respectively, in a transmission manner;
or:
a planetary gear set, the workpiece being mounted on a planetary gear capable of performing revolution motion and rotation motion.

Compared with the prior art, the present disclosure has the following beneficial effects.

1. In the present disclosure, the workpiece performs bi-directional planetary motion in the solid electro-conductive media inside the cathode container, so that the workpiece as a whole can be polished at one time within one planetary motion period, with a high polishing efficiency.

2. By means of the electrochemical polishing method employing solid electro-conductive media with bi-directional planetary motion in the present disclosure, complex-shaped parts or curved surfaces can be effectively polished, and the uniformity of material removal from various surfaces of the workpiece is maintained, with a high polishing quality.

3. By means of the electrochemical polishing method employing solid electro-conductive media with bi-directional planetary motion in the present disclosure, the electrolyte in the gap of the solid electro-conductive media is absorbed during the polishing, which reduces the risk of workers coming into contact with the strong acidic electrolyte, eliminates waste electrolyte production, and is environmentally friendly. In the present disclosure, reducing the amount of water consumed in the electrochemical polishing industry at the source by means of the new polishing method and controlling wastewater pollution are the key issues in realizing green electrochemical manufacturing.

### BRIEF DESCRIPTION OF THE DRAWINGS

FIG. 1 demonstrates a process of an electrochemical polishing method employing solid electro-conductive media with bi-directional planetary motion provided in Example 1;

FIG. 2 shows the speed variation of ω₁ and ω₂ in the electrochemical polishing method in Example 1; and

FIG. 3 exhibits the comparison of effects before and after polishing by applying the electrochemical polishing method in Example 1 to a curved 316L stainless steel workpiece.

### DETAILED DESCRIPTION

### Example 1

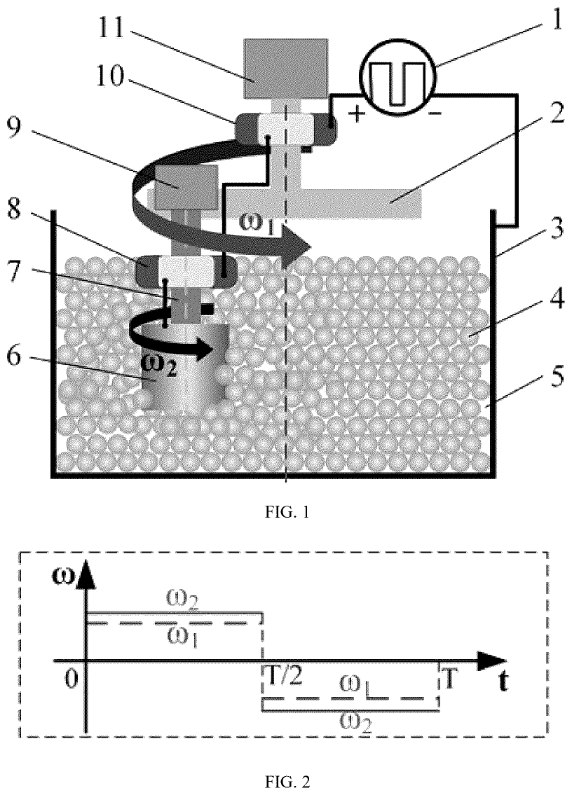

By reference to FIG. 1, the example provides an electrochemical polishing method employing solid electro-conductive media with bi-directional planetary motion, mainly including the following steps.

In step S1, a workpiece was submerged in solid electro-conductive media 4 inside a cathode container 3, and the workpiece and the cathode container 3 were connected to a positive pole and a negative pole of a polishing power source 1, to serve as an anode and a cathode, respectively, of an electrochemical reaction.

In step S2, the workpiece was driven to perform planetary motion in the solid electro-conductive media 4 along an inner wall of the cathode container 3.

In step S3, the polishing power supply 1 was turned on to polish the workpiece that performs the planetary motion.

In step S4, the polishing power supply 1 was turned off, and the workpiece was taken out, to obtain a polished workpiece.

The planetary motion included: revolution motion with an angular velocity of ω₁ and rotation motion with an angular velocity of ω₂, both always in the same direction, and reversed at least once in one planetary motion period T.

By means of the electrochemical polishing method of this example, one-time polishing of the entire workpiece can be achieved within one planetary motion period T, complex-shaped parts or curved surfaces can be effectively polished, and the uniformity of material removal from various surfaces of the workpiece can be maintained.

### Example 2

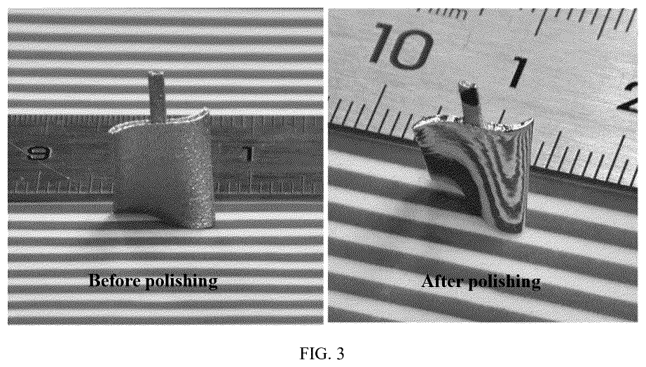

By reference to FIGS. 1-3, the example provides a polishing device applied to the electrochemical polishing method employing solid electro-conductive media with bi-directional planetary motion in Example 1. The polishing device includes: a polishing power supply 1; a revolution platform 2; a cathode container 3; solid electro-conductive media 4; a rotation connecting rod 7; a first electro-conductive slip ring 8; a rotation drive motor 9; a second electro-conductive slip ring 10; and a revolution drive motor 11.

The first electro-conductive slip ring 8 and the second electro-conductive slip ring 10 jointly form an electro-conductive slip ring assembly.

The polishing device is operated as follows.

The solid electro-conductive media 4, which had absorbed electrolytes, were placed in the cathode container 3. Since the solid electro-conductive media 4 had a certain diameter, the gap therebetween was filled with air 5.

An anode (workpiece) 6 was fixed to the rotation connecting rod 7, and the rotation connecting rod 7 was directly driven by the rotation drive motor 9. The rotation drove motor 9 was mounted on the revolution platform 2, and the revolution platform 2 was connected to the revolution drive motor 11. The rotation of the revolution drive motor 11 drove the revolution platform 2, the rotation drive motor 9 and the anode (workpiece) 6 to rotate, allowing the anode (workpiece) 6 to perform revolution motion.

In addition, the rotation drive motor 9 simultaneously drove the anode (workpiece) 6 to perform rotation to form planetary rotary motion. The magnitude and direction of a revolution angular velocity ω₁ and a rotation angular velocity ω₂ in the process of the planetary rotary motion were shown in FIG. 2. The revolution angular velocity ω₁ and the rotation angular velocity ω₂ were always in the same direction, which were reversed in this example as follows: after co-rotating in the same direction for a period of T/2, they were reversed for a period of T/2, so that the bi-directional planetary motion with a period of T was formed. The adjustment mode was not limited to this, and it was ensured that each time when ω₁ and ω₂ were forward and reverse occupied T/2 in the entire period of T, or adjustment corresponding to the specific workpiece was made, but at least one reverse was carried out.

The negative pole of the polishing power supply 1 was connected to the cathode container 3, and the positive pole of the polishing power supply 1 was connected to the anode (workpiece) 6. The specific connection mode was as follows: the anode (workpiece) 6 was connected to the rotation connecting rod 7 that was electrically conductive and insulated from the rotation drive motor 9, the rotation connecting rod 7 was connected to a movable ring of the first electro-conductive slip ring 8, and a static ring of the first electro-conductive slip ring 8 was connected to a movable ring of the second electro-conductive slip ring 10, and a static ring of the second electro-conductive slip ring 10 was connected to the positive pole of the polishing power supply 1.

The polishing power supply 1 was turned on, and a potential difference was generated between the anode (workpiece) 6 and the cathode container 3. “Electric bridges” were formed by the mutual collision among the solid electro-conductive media 4, the solid electro-conductive media 4 were in contact with the anode (workpiece) 6, and metal atoms on a surface of the anode (workpiece) 6 were oxidized into metal ions, which were taken away by the solid electro-conductive media 4, so that material removal was generated.

Finally, after the polishing lasted for several periods of bi-directional planetary motion of T, the polishing power supply 1, the rotation drive motor 9 and the revolution drive motor 11 were turned off, and the anode (workpiece) 6 was taken out, so that the overall polished workpiece was obtained.

It is to be noted that in the electrochemical polishing method employing solid electro-conductive media with bi-directional planetary motion of the present disclosure, the individual pieces are common standard pieces or parts known to those skilled in the art, and the structure and principles thereof are known to those skilled in the art through technical manuals or through conventional experimental methods.

The specific operation principle is as follows.

The present disclosure mainly includes the polishing power source 1, the cathode container 3, the solid electro-conductive media 4 and the drive member for driving the workpiece to perform planetary motion in the solid electro-conductive media along the inner wall of the cathode container. The drive member includes the rotation connecting rod 7, the first electro-conductive slip ring 8, the rotation drive motor 9, the second electro-conductive slip ring 10, and the revolution drive motor 11.

The solid electro-conductive media 4 are solid spherical particles that absorb a certain amount of electrolytes and have the electrical conductivity necessary for electrochemical polishing.

The anode (workpiece) 6 is connected to the positive pole of the polishing power supply 1, and the cathode container 3 is connected to the negative pole of the polishing power supply 1.

The polishing power supply 1 provides driving force for the electrochemical reaction of oxidizing and dissolving metal monomers on the anode (workpiece) 6.

The drive member achieves a stable connection of the anode (workpiece) 6 to the positive pole of the polishing power supply 1 via the first electro-conductive slip ring 8 and the second electro-conductive slip ring 10 while the anode (workpiece) 6 performs revolution motion and rotation motion. The planetary motion is achieved by means of the rotation drive motor 9 and the revolution drive motor 11, which are stepping motors, and can be synchronously adjusted for magnitude and direction of the rotation speed according to demand. The anode (workpiece) 6 is overall polished by entirely submerging in the solid electro-conductive media 4 during the polishing.

It is readily understood that, on the basis of one or several examples provided in the present application, those skilled in the art may combine, divide, and reorganize the examples of the present application to obtain other examples, none of which is beyond the scope of protection of the present application.

The present disclosure and embodiments thereof are schematically described above, and the description has no limitation on the present disclosure. What is shown in the examples are only a part of embodiments of the present disclosure, and the actual structure is not limited thereto. In sum, for those ordinary skilled in the art inspired by the above examples, without departing from the creative purpose of the present disclosure, structures and examples similar to the technical solutions designed without creativeness are belong to the scope of protection of the present disclosure.

1. An electrochemical polishing method employing solid electro-conductive media with bi-directional planetary motion, comprising:
submerging a workpiece in solid electro-conductive media inside a cathode container, connecting the workpiece and the cathode container to a positive pole and a negative pole of a polishing power source, to serve as an anode and a cathode, respectively, of an electrochemical reaction, and
driving the workpiece to perform planetary motion in the solid electro-conductive media along an inner wall of the cathode container while turning on the polishing power supply to polish the workpiece, wherein
the planetary motion comprises: revolution motion with an angular velocity of ω₁ and rotation motion with an angular velocity of ω₂, both always in the same direction, and reversed at least once in one planetary motion period T.

2. The electrochemical polishing method employing solid electro-conductive media with bi-directional planetary motion according to claim 1, wherein in the one planetary motion period T, the time when ωj and ω₂ are forward and reverse is T/2.

3. The electrochemical polishing method employing solid electro-conductive media with bi-directional planetary motion according to claim 1, wherein the solid electro-conductive media are spherical particles, having a diameter in the range of 0.1-2.0 mm and pore structures internally, and are formed by styrene or acrylic acid ion exchange resin.

4. The electrochemical polishing method employing solid electro-conductive media with bi-directional planetary motion according to claim 1, wherein the pore structures in the electro-conductive media serve to store electrolytes, making solid dielectrics electrically conductive in the polishing process.

5. The electrochemical polishing method employing solid electro-conductive media with bi-directional planetary motion according to claim 1, wherein the cathode container is electrically conductive and made of stainless steel.

6. The electrochemical polishing method employing solid electro-conductive media with bi-directional planetary motion according to claim 1, wherein the power supply is a pulsed direct current power supply with a pulse period of 0.1-1 ms and a duty ratio of 50%-90%.

7. The electrochemical polishing method employing solid electro-conductive media with bi-directional planetary motion according to claim 1, wherein the workpiece is connected to the positive pole of the polishing power supply via an electro-conductive slip ring during the planetary motion.

8. The electrochemical polishing method employing solid electro-conductive media with bi-directional planetary motion according to claim 1, wherein the planetary motion period T is 1-40 min.

9. An electrochemical polishing device employing solid electro-conductive media with bi-directional planetary motion for performing an electrochemical polishing method employing solid electro-conductive media with bi-directional planetary motion according to claim 1, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

10. An electrochemical polishing device employing solid electro-conductive media with bi-directional planetary motion for performing an electrochemical polishing method employing solid electro-conductive media with bi-directional planetary motion according to claim 2, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

11. An electrochemical polishing device employing solid electro-conductive media with bi-directional planetary motion for performing an electrochemical polishing method employing solid electro-conductive media with bi-directional planetary motion according to claim 3, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

12. An electrochemical polishing device employing solid electro-conductive media with bi-directional planetary motion for performing an electrochemical polishing method employing solid electro-conductive media with bi-directional planetary motion according to claim 4, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

13. An electrochemical polishing device employing solid electro-conductive media with bi-directional planetary motion for performing an electrochemical polishing method employing solid electro-conductive media with bi-directional planetary motion according to claim 5, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

14. An electrochemical polishing device employing solid electro-conductive media with bi-directional planetary motion for performing an electrochemical polishing method employing solid electro-conductive media with bi-directional planetary motion according to claim 6, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

15. An electrochemical polishing device employing solid electro-conductive media with bi-directional planetary motion for performing an electrochemical polishing method employing solid electro-conductive media with bi-directional planetary motion according to claim 7, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

16. An electrochemical polishing device employing solid electro-conductive media with bi-directional planetary motion for performing an electrochemical polishing method employing solid electro-conductive media with bi-directional planetary motion according to claim 8, comprising:
a polishing power supply, a positive pole thereof being used for connecting a workpiece;
a cathode container, connected to a negative pole of the polishing power supply, and used for holding solid electro-conductive media; and
a drive member, used for driving the workpiece to perform planetary motion in the solid electro-conductive media along an inner wall of the cathode container.

17. The electrochemical polishing device employing solid electro-conductive media with bi-directional planetary motion according to claim 9, wherein the workpiece is connected to the positive pole of the polishing power supply via an electro-conductive slip ring assembly; the drive member comprising:
a revolution platform and a rotation connecting rod mounted thereon, the workpiece being mounted at a tail end of the rotation connecting rod, and the revolution platform and the rotation connecting rod being connected to a revolution drive motor and a rotation drive motor, respectively, in a transmission manner;
or:
a planetary gear set, the workpiece being mounted on a planetary gear capable of performing revolution motion and rotation motion.

18. The electrochemical polishing device employing solid electro-conductive media with bi-directional planetary motion according to claim 10, wherein the workpiece is connected to the positive pole of the polishing power supply via an electro-conductive slip ring assembly; the drive member comprising:
a revolution platform and a rotation connecting rod mounted thereon, the workpiece being mounted at a tail end of the rotation connecting rod, and the revolution platform and the rotation connecting rod being connected to a revolution drive motor and a rotation drive motor, respectively, in a transmission manner;
or:
a planetary gear set, the workpiece being mounted on a planetary gear capable of performing revolution motion and rotation motion.

19. The electrochemical polishing device employing solid electro-conductive media with bi-directional planetary motion according to claim 11, wherein the workpiece is connected to the positive pole of the polishing power supply via an electro-conductive slip ring assembly; the drive member comprising:
a revolution platform and a rotation connecting rod mounted thereon, the workpiece being mounted at a tail end of the rotation connecting rod, and the revolution platform and the rotation connecting rod being connected to a revolution drive motor and a rotation drive motor, respectively, in a transmission manner;
or:
a planetary gear set, the workpiece being mounted on a planetary gear capable of performing revolution motion and rotation motion.

20. The electrochemical polishing device employing solid electro-conductive media with bi-directional planetary motion according to claim 12, wherein the workpiece is connected to the positive pole of the polishing power supply via an electro-conductive slip ring assembly; the drive member comprising:
a revolution platform and a rotation connecting rod mounted thereon, the workpiece being mounted at a tail end of the rotation connecting rod, and the revolution platform and the rotation connecting rod being connected to a revolution drive motor and a rotation drive motor, respectively, in a transmission manner;
or:
a planetary gear set, the workpiece being mounted on a planetary gear capable of performing revolution motion and rotation motion.
